(19) United States
(12) Patent Application Publication
(10) Pub. No.: US 2013/0201635 A1
(43) Pub. Date: Aug. 8, 2013

(54) FLUORINATED SILANE COATING COMPOSITIONS FOR THIN WAFER BONDING AND HANDLING

(71) Applicant: BREWER SCIENCE INC., Rolla, MO (US)

(72) Inventor: Gu Xu, Rolla, MO (US)

(73) Assignee: BREWER SCIENCE INC., Rolla, MO (US)

(21) Appl. No.: 13/763,251

(22) Filed: Feb. 8, 2013

Related U.S. Application Data
(60) Provisional application No. 61/596,490, filed on Feb. 8, 2012.

(51) Int. Cl. B32B 7/06; H05K 1/18

(52) U.S. Cl. CPC B32B 7/06; H05K 1/18
USPC 361/748; 156/247; 428/421; 428/422; 428/119; 428/172

(57) ABSTRACT

This invention is related to compositions that prepare substrate surfaces to enable temporary wafer bonding during microelectronics manufacturing, especially using a zonal bonding process. This invention, which comprises compositions made from fluorinated silanes blended in a polar solvent, can be used to form surface coatings or treatments having a high contact angle with water (>85°). The resulting silane solutions are stable at room temperature for longer than one month.

### RELATED APPLICATIONS

This application claims the priority benefit of a provisional application entitled FLUORINATED SILANE COATING COMPOSITIONS FOR THIN WAFER BONDING AND HANDLING, Ser. No. 61/596,490, filed Feb. 8, 2012, incorporated by reference herein.

### BACKGROUND OF THE INVENTION

1. Field of the Invention

The present invention is broadly concerned with novel temporary wafer bonding methods that involve use of a carrier wafer having a nonstick surface.

2. Description of the Prior Art

The wafer thinning process often requires bonding a wafer that will undergo thinning to a carrier wafer that supports the first wafer during the thinning process. In some temporary bonding schemes, such as ZoneBOND® zonal bonding from Brewer Science, Inc. (described in U.S. Patent Publication No. 2009/0218560, incorporated by reference herein), such carrier wafers may require pretreatment with a coating before the wafers are bonded together. A solution of (heptadecafluoro-1,1,2,2-tetrahydrodecyl)trichlorosilane in a fluorinated solvent, such as 3M FC-40 Fluorinert™ electronic liquid, has been used for carrier wafer preparation. However, the silane/FC-40 solution is not a practical coating material because it is unstable, and FC-40 is restricted for use in microelectronics manufacturing because of environmental concerns. Solutions made from (heptadecafluoro-1,1,2,2-tetrahydrodecyl) trichlorosilane alone in an industry-accepted, safe solvent are not stable and have only a few days of shelf life.

There is a need for new compositions that utilize industry-accepted, safe solvents that can be cost-effectively applied using standard spin-coating equipment and that have extended shelf lives (i.e., longer than three months).

### SUMMARY OF THE INVENTION

The present invention fills the above need by providing novel methods and microelectronic structures. In one embodiment, a temporary bonding method is provided. The method comprises providing a stack comprising:

a first substrate having a back surface and a second surface;

a bonding layer adjacent the second surface; and

a second substrate having a first surface, where the first surface includes a nonstick layer.

The nonstick layer is formed from a composition comprising a fluorinated silane and less than about 5% by weight total of fluorinated and perfluorinated solvents, based upon the total weight of the composition taken as 100% by weight. The nonstick layer is adjacent the bonding layer. Finally, the method further comprises separating the first and second substrates.

In another embodiment, the invention comprises an article comprising:

a first substrate having a back surface and a second surface;

a bonding layer adjacent the second surface; and

a second substrate having a first surface, where the first surface includes a nonstick layer.

The nonstick layer is formed from a composition comprising a fluorinated silane; and less than about 5% by weight total of fluorinated and perfluorinated solvents, based upon the total weight of the composition taken as 100% by weight. Finally, the nonstick layer is adjacent the bonding layer.

### BRIEF DESCRIPTION OF THE DRAWINGS

FIG. 1 is a cross-sectional view of a schematic drawing showing a preferred embodiment of the invention; and

FIG. 2 is a graph depicting the silane concentration vs. the contact angle of the formulations prepared in Examples 14-18.

### DETAILED DESCRIPTION OF THE PREFERRED EMBODIMENTS

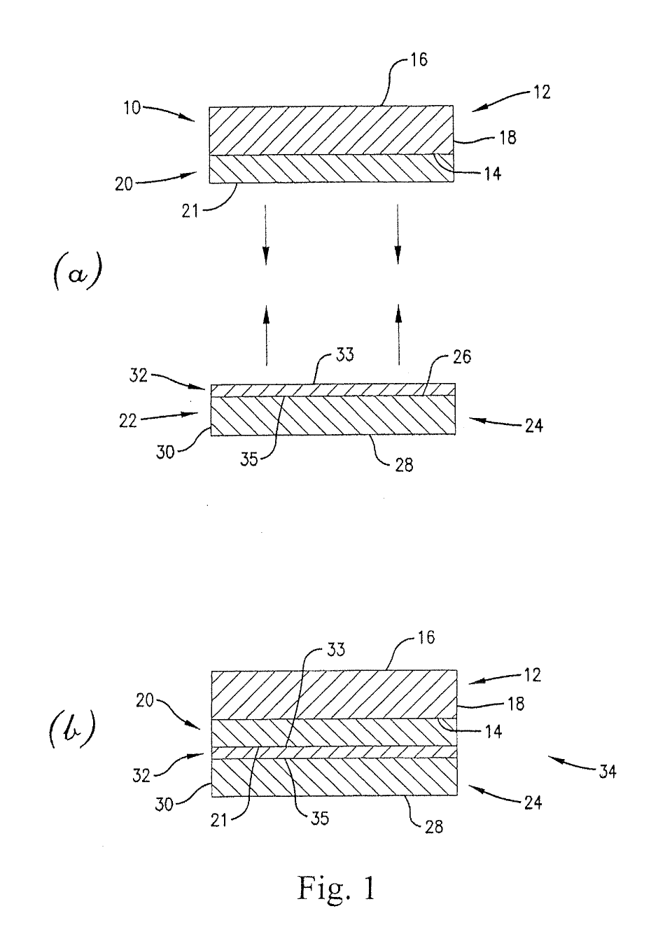

Referring to FIG. 1(a) (not to scale), a precursor structure 10 is depicted in a schematic and cross-sectional view. Structure 10 includes a first substrate 12. Substrate 12 has a front or device surface 14, a back surface 16, and an outermost edge 18. Although substrate 12 can be of any shape, it would typically be circular in shape. Preferred first substrates 12 include device wafers such as those whose device surfaces comprise arrays of devices (not shown) selected from the group consisting of integrated circuits. MEMS, microsensors, power semiconductors, light-emitting diodes, photonic circuits, interposers, embedded passive devices, and other microdevices fabricated on or from silicon and other semiconducting materials such as silicon-germanium, gallium arsenide, and gallium nitride. The surfaces of these devices commonly comprise structures (again, not shown) formed from one or more of the following materials: silicon, polysilicon, silicon dioxide, silicon (oxy)nitride, metals (e.g., copper, aluminum, gold, tungsten, tantalum), low k dielectrics, polymer dielectrics, and various metal nitrides and silicides. The device surface 14 can also include at least one structure selected from the group consisting of: solder bumps; metal posts; metal pillars; and structures formed from a material selected from the group consisting of silicon, polysilicon, silicon dioxide, silicon (oxy)nitride, metal, low k dielectrics, polymer dielectrics, metal nitrides, and metal silicides.

A composition is applied to the first substrate 12 to form a bonding layer 20 on the device surface 14, as shown in FIG. 1(a). Bonding layer 20 has an upper surface 21 remote from first substrate 12, and preferably, the bonding layer 20 is formed directly adjacent the device surface 14 (i.e., without any intermediate layers between the bonding layer 20 and substrate 12). Although bonding layer 20 is shown to cover the entire device surface 14 of first substrate 12, it will be appreciated that it could be present on only portions or “zones” of device surface 14, as shown in U.S. Patent Publication No. 2009/0218560.

The bonding composition can be applied by any known application method, with one preferred method being spin-coating the composition at speeds of from about 500 rpm to about 5,000 rpm (preferably from about 500 rpm to about 2,000 rpm) for a time period of from about 5 seconds to about 120 seconds (preferably from about 30 seconds to about 90 seconds). After the composition is applied, it is preferably heated to a temperature of from about 80° C. to about 250° C., and more preferably from about 170° C. to about 220° C. and for time periods of from about 60 seconds to about 8 minutes (preferably from about 90 seconds to about 6 minutes). Depending upon the composition used to form the bonding layer 20, baking can also initiate a crosslinking reaction to cure the layer 20. In some embodiments, it is preferable to subject the layer to a multi-stage bake process, depending upon the composition utilized. Also, in some instances, the above application and bake process can be repeated on a further aliquot of the composition, so that the first bonding layer 20 is “built” on the first substrate 12 in multiple steps. In yet another embodiment, the bonding layer 20 can be provided in the form of a pre-formed, dry film rather than spin-applied. The film can then be adhered to the first substrate 12.

The materials from which bonding layer 20 is formed should be capable of forming a strong adhesive bond with the first and second substrates 12 and 24, respectively. Anything with an adhesion strength of greater than about 50 psig, preferably from about 80 psig to about 250 psig, and more preferably from about 100 psig to about 150 psig, as determined by ASTM D4541/D7234, would be desirable for use as bonding layer 20.

Advantageously, the compositions for use in forming bonding layer 20 can be selected from commercially available bonding compositions that would be capable of being formed into layers possessing the above adhesive properties, while being removable by heat and/or solvent. Typical such compositions are organic and will comprise a polymer or oligomer dissolved or dispersed in a solvent system. The polymer or oligomer is typically selected from the group consisting of polymers and oligomers of cyclic olefins, epoxies, acrylics, silicones, styrenics, vinyl halides, vinyl esters, polyamides, polyimides, polysulfones, polyethersulfones, cyclic olefins, polyolefin rubbers, and polyurethanes, ethylene-propylene rubbers, polyamide esters, polyimide esters, polyacetals, and polyvinyl butyral. Typical solvent systems will depend upon the polymer or oligomer selection. Typical solids contents of the compositions will range from about 1% to about 60% by weight, and preferably from about 3% to about 40% by weight, based upon the total weight of the composition taken as 100% by weight. Some suitable compositions are described in U.S. Patent Publication Nos. 2007/0185310, 2008/0173970, 2009/0038750, and 2010/0112305, each incorporated by reference herein.

A second precursor structure 22 is also depicted in a schematic and cross-sectional view in FIG. 1(a). Second precursor structure 22 includes a second substrate 24. In this embodiment, second substrate 24 is a carrier wafer. That is, second substrate 24 has a front or carrier surface 26, a back surface 28, and an outermost edge 30. Although second substrate 24 can be of any shape, it would typically be circular in shape and sized similarly to first substrate 12. Preferred second substrates 24 include silicon, sapphire, quartz, metals (e.g., aluminum, copper, steel), and various glasses and ceramics.

A nonstick composition is applied to the second substrate 24 to form a nonstick layer 32 on the carrier surface 26, as shown in FIG. 1(a). (Alternatively, structure 22 can be provided already formed.) Nonstick layer 32 has an upper surface 33 remote from second substrate 24, and a lower surface 35 adjacent second substrate 24. Preferably, the nonstick layer 32 is formed directly adjacent the carrier surface 26 (i.e., without any intermediate layers between the second bonding layer 32 and second substrate 24).

The composition can be applied by any known application method, with one preferred method being spin-coating the composition at speeds of from about 500 rpm to about 5,000 rpm (preferably from about 500 rpm to about 2,000 rpm) for a time period of from about 5 seconds to about 120 seconds (preferably from about 30 seconds to about 90 seconds). After the composition is applied, it is preferably heated to a temperature of from about 100° C. to about 300° C., and more preferably from about 150° C. to about 250° C. and for time periods of from about 30 seconds to about 5 minutes (preferably from about 90 seconds to about 3 minutes). Nonstick layer 32 preferably has a thickness of less than about 100 nm, preferably from about 1 nm to about 50 nm, and more preferably from about 1 nm to about 10 nm. Preferred compositions for use to form nonstick layer 32 comprise fluorinated silanes.

Preferred fluorinated silanes are selected from the group consisting of (heptadecafluoro-1,1,2,2-tetrahydrodecyl)trichlorosilane, (heptadecafluoro-1,1,2,2-tetrahydrodecyl)trimethoxysilane), (heptadecafluoro-1,1,2,2-tetrahydrodecyl)dimethylchlorosilane, (heptadecafluoro-1,1,2,2-tetrahydrodecyl)methyldichlorosilane, (3-heptafluoroisopropoxy)propyltrichlorosilane, (tridecafluoro-1,1,2,2-tetrahydrooctyl)trichlorosilane, (tridecafluoro-1,1,2,2-tetrahydrooctyl)triethoxysilane, (tridecafluoro-1,1,2,2-tetrahydrooctyl)trimethoxysilane, (tridecafluoro-1,1,2,2-tetrahydrooctyl)dimethylchlorosilane, (tridecafluoro-1,1,2,2-tetrahydrooctyl)methyldichlorosilane, and mixtures of the foregoing. The composition preferably comprises from about 0.01% to about 3% by weight, more preferably from about 0.03% to about 1% by weight, and even more preferably from about 0.05% to about 0.4% by weight fluorinated silane, based upon the total weight of the composition taken as 100% by weight. A particularly preferred composition according to the invention comprises a blend of from about 0.1% to about 5% by weight (heptadecafluoro-1,1,2,2-tetrahydrodecyl)trichlorosilane and from about 0.1% to about 5% by weight (heptadecafluoro-1,1,2,2-tetrahydrodecyl)trimethoxysilane), with the % by weight being based upon the total weight of the composition taken as 100% by weight.

The nonstick composition can also include a catalyst. Suitable catalysts include those selected from the group consisting of hydrochloric acid, acetic acid, hydrobromic acid, sulfuric acid, and nitric acid. In embodiments where a catalyst is included, the composition preferably comprises from about 0.01% to about 0.8% by weight, more preferably from about 0.05% to about 0.6% by weight, and even more preferably from about 0.1% to about 0.4% by weight catalyst, based upon the total weight of the composition taken as 100% by weight.

In some embodiments, the nonstick composition comprises water, which acts as a reactant in the formulation. In these embodiments, the water is present at levels of from about 0.1% to about 8% by weight, preferably from about 0.1% to about 5% by weight, and more preferably from about 0.1% to about 3% by weight, based upon the total weight of the composition taken as 100% by weight.

The nonstick compositions also comprise an industry-accepted, safe solvent, and typically a polar solvent. Suitable solvents include those selected from the group consisting of propylene glycol monomethyl ether (PGME), 1-butanol, hexyl alcohol, propoxy propanol (PnP), and mixtures thereof. The composition preferably comprises from about 80% to about 99.9% by weight, more preferably from about 90% to about 99% by weight, and even more preferably from about 95% to about 99% by weight of this solvent, based upon the total weight of the composition taken as 100% by weight.

Preferred nonstick compositions are also free of solvents whose use is restricted in microelectronic manufacturing due to environmental concerns. More particularly, the compositions comprise less than about 5% by weight total of such solvents, preferably less than about 1% by weight total of such solvents, and even more preferably about 0% by weight total of such solvents, based upon the total weight of the composition taken as 100% by weight. Examples of solvents that are limited in, or excluded from, the nonstick composition include those selected from the group consisting of fluorinated solvents (e.g., FC-40 Fluorinert™ electronic liquid from 3M) and perfluorinated solvents.

In one embodiment, the nonstick composition consists essentially of, or even consists of, the fluorinated silane(s), catalyst, and polar solvent(s). In another embodiment, the nonstick composition consists essentially of, or even consists of, the fluorinated silane(s) and polar solvent(s).

The nonstick composition can be formed by simply mixing the above ingredients together. Advantageously, the resulting composition is highly stable. That is, the composition remains stable when stored at room temperature for at least about one month, preferably at least about 6 months, and more preferably at least about 12 months. As used herein, “stable” means that after these time periods, the composition retains acceptable coating quality as well as the contact angles described herein.

Referring to structure 22 of FIG. 1(a) again, although nonstick layer 32 is shown to cover the entire surface 26 of second substrate 24, it will be appreciated that it could be present on only portions or “zones” of carrier surface 26 similar to as was described with bonding layer 20. Regardless, the dried/cured layer 32 will have a high contact angle with water, which effects polymer release during the debonding step (discussed below). Typical contact angles (measured as described in Example 1) will be at least about 60°, preferably from about 60° to about 120°, and more preferably from about 90° to about 110°. The nonstick layer 32 also preferably has an adhesion strength of less than about 50 psig, preferably less than about 35 psig, and more preferably from about 1 psig to about 30 psig, determined as described above.

Structures 10 and 22 are then pressed together in a face-to-face relationship, so that upper surface 21 of bonding layer 20 is in contact with upper surface 33 of nonstick layer 32 (FIG. 1(b)). While pressing, sufficient pressure and heat are applied for a sufficient amount of time so as to effect bonding of the two structures 10 and 22 together to form bonded stack 34. The bonding parameters will vary depending upon the composition from which bonding layer 20 is formed, but typical temperatures during this step will range from about 150° C. to about 375° C., and preferably from about 160° C. to about 350° C., with typical pressures ranging from about 1,000 N to about 5,000 N, and preferably from about 2,000 N to about 4,000 N, for a time period of from about 30 seconds to about 5 minutes, and more preferably from about 2 minutes to about 4 minutes.

At this stage, the first substrate 12 can be safely handled and subjected to further processing that might otherwise have damaged first substrate 12 without being bonded to second substrate 24. Thus, the structure can safely be subjected to backside processing such as back-grinding, CMP, etching, metal and dielectric deposition, patterning (e.g., photolithography, via etching), passivation, annealing, and combinations thereof, without separation of substrates 12 and 24 occurring, and without infiltration of any chemistries encountered during these subsequent processing steps. Not only can bonding layer 20 survive these processes, it can also survive processing temperatures up to about 450° C., preferably from about 200° C. to about 400° C., and more preferably from about 200° C. to about 350° C.

Once processing is complete, the substrates 12 and 24 can be separated by any number of separation methods (not shown). One method involves dissolving the bonding layer 20 in a solvent (e.g., limonene, dodecene, propylene glycol monomethyl ether (PGME)). Alternatively, substrates 12 and 24 can also be separated by first mechanically disrupting or destroying the periphery of bonding layer 20 using laser ablation, plasma etching, water jetting, or other high energy techniques that effectively etch or decompose bonding layer 20. It is also suitable to first saw or cut through the bonding layer 20 or cleave the layer 20 by some equivalent means. Regardless of which of the above means is utilized, a low mechanical force (e.g., finger pressure, gentle wedging) can then be applied to completely separate the substrates 12 and 24.

The most preferred separation method involves heating the bonded stack 34 to temperatures of at least about 100° C., preferably from about 150° C. to about 220° C., and more preferably from about 180° C. to about 200° C. It will be appreciated that at these temperatures, the bonding layer 20 will soften, allowing the substrates 12 and 24 to be separated (e.g., by a slide debonding method, such as that described in U.S. Patent Publication No. 2008/0200011, incorporated by reference herein). After separation, any remaining bonding layer 20 can be removed with a solvent capable of dissolving the particular layer 20.

Finally, in the above embodiments, the nonstick layer 32 is shown on a second substrate 24 that is a carrier wafer, while bonding layer 20 is shown on a first substrate 12 that is a device wafer. It will be appreciated that this substrate/layer scheme could be reversed. That is, the nonstick layer 32 could be formed on first substrate 12 (the device wafer) while bonding layer 20 is formed on second substrate 24 (the carrier wafer). The same compositions and processing conditions would apply to this embodiment as those described above.

### EXAMPLES

The following examples set forth preferred methods in accordance with the invention. It is to be understood, however, that these examples are provided by way of illustration and nothing therein should be taken as a limitation upon the overall scope of the invention.

### Example 1

### Formulation of a 1.5% Silane Solution

In this Example, 98.50 grams of PGME (Ultra Pure, Inc., Castroville, Calif., USA), 0.50 gram of (heptadecafluoro-1,1,2,2-tetrahydrodecyl)trimethoxysilane) (Gelest, Morrisville, Pa., USA), and 1.00 gram of (heptadecafluoro-1,1,2,2-tetrahydrodecyl)trichlorosilane) (Gelest, Morrisville, Pa., USA) were added to a 250-ml glass bottle. The resulting solution was stirred until all silanes were dissolved, and then the solution was filtered twice through a 0.1-μm disk filter (Whatman, Inc., Florham Park, N.J., USA). The total silane concentration in this solution was 1.5%.

### Example 2

### Formulation of a 1.0% Silane Solution

In this procedure, 99.00 grams of PGME, 0.50 gram of (heptadecafluoro-1,1,2,2-tetrahydro-decyl)trimethoxysilane), and 0.50 gram of (heptadecafluoro-1,1,2,2-tetrahydrodecyl)trichlorosilane) were added to a 250-ml glass bottle. The solution was stirred until all silanes were dissolved, and then the solution was filtered twice through a 0.1-μm disk filter. The total silane concentration in this solution was 1.0%.

### Example 3

### Formulation of a 1.5% Silane Solution

In this Example, 98.50 grams of PGME, 1.00 gram of (heptadecafluoro-1,1,2,2-tetrahydrodecyl)trimethoxysilane), and 0.50 gram of (heptadecafluoro-1,1,2,2-tetrahydrodecyl)trichlorosilane) were added to a 250-ml glass bottle. The solution was stirred until all silanes were dissolved, and then the solution was filtered twice through a 0.1-μm disk filter. The total silane concentration in this solution was 1.5%.

### Example 4

### Formulation of a 0.75% Silane Solution Made by Solvent Dilution

In this procedure, 40.00 grams of PGME and 40.00 grams of the solution prepared in Example 3 were added to a 250-ml glass bottle. The solution was mixed thoroughly and then filtered twice through a 0.1-μm disk filter. The total silane concentration in this solution was 0.75%.

### Example 5

### Formulation of a 0.5% Silane Solution Made by Solvent Dilution

In this Example, 60.00 grams of PGME and 30.00 grams of the solution prepared in Example 3 were added to a 250-ml glass bottle. The solution was mixed thoroughly and then filtered twice through a 0.1-μm disk filter. The total silane concentration in this solution was 0.5%.

### Example 6

### Formulation of a 0.15% Silane Solution Made by Solvent Dilution

In this procedure, 90.00 grams of PGME and 10.00 grams of the solution prepared in Example 3 were added to a 250-ml glass bottle. The solution was mixed thoroughly and then filtered twice through a 0.1-μm disk filter. The total silane concentration in this solution was 0.15%.

### Example 7

### Coating Performance of Examples 1 Through 6

The solutions from Examples 1 through 6 were each spin-coated onto a 100-mm silicon wafer using a spin coater (Cee® 100CB from Brewer Science, Inc., Rolla, Mo.) at a spin speed of 1,250 rpm (250 rpm/s ramp) for 30 seconds, followed by baking on a hotplate (Cee® 100CB from Brewer Science, Inc., Rolla, Mo.) at 220° C. for 120 seconds. Each of the coatings made from the solutions was good in quality based on visual observation. The contact angle with water of the resulting films was measured using a VCA Optima tool (AST Products, Inc., Billerica, Mass., USA). The measured contact angles are listed in Table 1.

TABLE 1
Characterization of Examples 1-6 and Performance
as Coatings on Silicon Wafers

| | SOLUTION | COATING | CONTACT ANGLE |
|---|---|---|---|
| SAMPLE | APPEARANCE | QUALITY* | WITH WATER |
| Example 1 | Clear | Good | 108° |
| Example 2 | Clear | Good | 102° |
| Example 3 | Clear | Good | 110° |
| Example 4 | Clear | Good | 114° |
| Example 5 | Clear | Good | 106° |
| Example 6 | Clear | Good | 103° |

*Based on visual observation.

### Example 8

### Wafer Bonding and Debonding with Treated Wafer

The silane solution from Example 3 was spin-coated onto a 200-mm silicon wafer at 1,250 rpm (250 rpm/s ramp) for 30 seconds, followed by baking at 220° C. for 120 seconds. The resulting coating on the wafer had a contact angle with water of 110°.

ZoneBond® 5150 material (Brewer Science, Inc., Rolla, Mo., USA) was coated onto another 200-mm silicon wafer. The following coating and baking process was used to coat the second wafer:

Spin coating:
Spin-coating tool: (Cee® 100CB from Brewer Science, Inc., Rolla, Mo.)
Dispense ZoneBond® 5150 material: 30 rpm, 300 rpm/s ramp, for 10 seconds
Spread spin: 300 rpm, 3,000 rpm/s ramp, for 5 seconds
Final spin: 2,000 rpm, 3,000 rpm/s ramp, for 30 seconds

Baking:
Hotplate tool: (Cee® 100CB from Brewer Science, Inc., Rolla, Mo.)
60° C. for 1 minute, then 80° C. for 1 minute, and then 220° C. for 2 minutes

The two wafers prepared as described above were bonded together in a face-to-face relationship with 5,800 N of bonding pressure under vacuum at 220° C. for 3 minutes in a vacuum chamber under pressure. After the bonded wafer pair was cooled to room temperature, the wafers were separated easily by means of a peeling process using a razor blade.

### Example 9

### Wafer Bonding Using a Treated Wafer and Subsequent Thinning of Another Wafer Bonded to the Treated Wafer

The center of a 200-mm silicon wafer was coated with the fluorinated silane solution from Example 3. A 3-mm zone at the wafer's outer edge was allowed to remain uncoated. This was accomplished by dispensing an epoxy-based photoresist (SU-8 2002, Microchem, Newton, Mass.) onto the surface of the wafer at the outer edge to coat a section of the wafer surface that was about 3 mm wide. The fluorinated silane composition was spin coated onto the central region of wafer surface, followed by baking on a hotplate at 100° C. for 1 minute. It was rinsed with PGME in a spin coater and baked at 100° C. for an additional minute. The epoxy-based photoresist was removed using acetone in a spin coater, leaving the edge untreated from the fluorinated silane solution.

ZoneBond® 5150 material was coated onto another 200-mm silicon wafer. The following coating and baking process was used to coat the second wafer:

Spin coating:
Spin-coating tool: (Cee® 100CB from Brewer Science, Inc., Rolla, Mo.)
Dispense ZoneBond® 5150 material: 30 rpm, 300 rpm/s ramp, for 10 seconds
Spread spin: 300 rpm, 3000 rpm/s ramp, for 5 seconds
Final spin: 2000 rpm, 3000 rpm/s ramp, for 30 seconds

Bake:
Hotplate tool: (Cee® 100CB from Brewer Science Inc. MO)
60° C. for 1 minute, then 80° C. for 1 minute, and then 220° C. for 2 minutes

The two wafers prepared as described above were bonded together in a face-to-face relationship with 5,800 N of bonding pressure under vacuum at 220° C. for 3 minutes in a vacuum chamber under pressure. The wafer pair was bonded together strongly. The wafer that was not treated with silane solution underwent grinding of its outer, unbonded side to thin the wafer. The wafer passed the grinding process test by successfully being thinned to a wafer thickness of 50 μm.

### Example 10

### Formulation of a 1.5% Silane Solution

In this Example, 98.51 grams of PGME (Ultra Pure, Inc., Castroville, Calif., USA), 1.01 grams of (heptadecafluoro-1,1,2,2-tetrahydrodecyl)trimethoxysilane) (Gelest, Morrisville, Pa., USA), and 0.50 gram of (heptadecafluoro-1,1,2,2-tetrahydrodecyl)trichlorosilane) (Gelest, Morrisville, Pa., USA) were added to a 250-ml glass bottle. Next, 0.18 gram of hydrochloric acid (37%) (Sigma-Aldrich, Mo.) was added. The solution was stirred until all silanes were dissolved, and then the solution was filtered twice through a 0.1-μm disk filter. The total silane concentration in this solution was 1.5%.

### Example 11

### Formulation of a 0.5% Silane Solution

In this procedure, 791.82 grams of PGME (Ultra Pure, Inc., Castroville, Calif., USA), 0.50 gram of hydrochloric acid (37%) (Sigma-Aldrich, Mo.), 3.68 grams of HPLC water (Sigma-Aldrich, Mo.), and 4.00 grams of (heptadecafluoro-1,1,2,2-tetrahydrodecyl)trimethoxysilane) (Gelest, Morrisville, Pa., USA) were added to a one-liter plastic bottle. The solution was stirred using a magnetic bar for 24 hours at ambient conditions, and then the solution was filtered twice through a 0.1-μm disk filter. The total silane concentration in this solution was 0.5%.

### Example 12

### Coating Performance of Examples 10 and 11

The solutions from Examples 10 and 11 were spin-coated onto 100-mm silicon wafers using a spin coater (Cee® 100CB from Brewer Science, Inc., Rolla, Mo.) at a spin speed of 1,250 rpm (250 rpm/s ramp) for 30 seconds, followed by baking on a hotplate (Cee® 100CB from Brewer Science Inc. MO) at 205° C. for 120 seconds. Each of the coatings made from the solutions were of good quality based on visual observation. The contact angle with water of the resulting films was measured using a VCA Optima tool (AST Products, Inc., Billerica, Mass., USA). The measured contact angles are listed in Table 2.

TABLE 2
Characterization of Examples 10-11 and Performance
as Coatings on Silicon Wafers

| | SOLUTION | COATING | CONTACT ANGLE |
|---|---|---|---|
| SAMPLE | APPEARANCE | QUALITY* | WITH WATER |
| Example 10 | Clear | Good | 112° |
| Example 11 | Clear | Good | 110° |

*Based on visual observation.

### Example 13

### Formulation of a 2% Trimethoxysilane Mother Liquor

In this procedure, 191.8152 grams of PGME (Ultra Pure, Inc., Castroville, Calif., USA), 4.00 grams of (heptadecafluoro-1,1,2,2-tetrahydrodecyl)trimethoxysilane) (Gelest, Morrisville, Pa., USA), 0.50 grams of hydrochloric acid (37%, Sigma-Aldrich, Mo.), and 3.6848 grams of HPLC water were added to a 1-liter plastic bottle. The solution was stirred using a magnetic bar for 4 hours at ambient conditions. This solution was the mother liquor with 2% of heptadecafluoro-1,1,2,2-tetrahydrodecyl)trimethoxysilane used in subsequent examples.

### Example 14

### Formulation of a 0.1% Trimethoxysilane Solution

In this Example, 190 grams of PGME (Ultra Pure, Inc., Castroville, Calif., USA) and 10 grams of the mother liquor from Example 13 were added to a 250-ml plastic bottle. The solution was stirred using a magnetic bar for 1 hour at ambient conditions, and then the solution was filtered through a 0.1-μm disk filter (Whatman, Inc., Florham Park, N.J., USA). The total silane concentration in this solution was 0.1%.

### Example 15

### Formulation of a 0.2% Trimethoxysilane Solution

In this procedure, 180 grams of PGME (Ultra Pure, Inc., Castroville, Calif., USA) and 20 grams of the mother liquor from Example 13 were added to a 250-ml plastic bottle. The solution was stirred using a magnetic bar for 1 hour at ambient conditions, and then the solution was filtered through a 0.1-μm disk filter (Whatman, Inc., Florham Park, N.J., USA). The total silane concentration in this solution was 0.2%.

### Example 16

### Formulation of a 0.3% Trimethoxysilane Solution

In this Example, 170 grams of PGME (Ultra Pure, Inc., Castroville, Calif., USA) and 30 grams of the mother liquor from Example 13 were added to a 250-ml plastic bottle. The solution was stirred using a magnetic bar for 1 hour at ambient conditions, and then the solution was filtered through a 0.1-μm disk filter (Whatman, Inc., Florham Park, N.J., USA). The total silane concentration in this solution was 0.3%.

### Example 17

### Formulation of a 0.4% Trimethoxysilane Solution

In this procedure, 160 grams of PGME (Ultra Pure, Inc., Castroville, Calif., USA) and 40 grams of the mother liquor from Example 13 were added to a 250-ml plastic bottle. The solution was stirred using a magnetic bar for 1 hour at ambient conditions, and then was filtered through a 0.1-μm disk filter (Whatman, Inc., Florham Park, N.J., USA). The total silane concentration in this solution was 0.4%.

### Example 18

### Formulation of a 0.5% Trimethoxysilane Solution

In this Example, 150 grams of PGME (Ultra Pure, Inc., Castroville, Calif., USA) and 50 grams of the mother liquor from Example 13 were added to a 250-ml plastic bottle. The solution was stirred using a magnetic bar for 1 hour at ambient conditions, and then was filtered through a 0.1-μm disk filter (Whatman, Inc., Florham Park, N.J., USA). The total silane concentration in this solution was 0.5%.

### Example 19

### Coating Performance of Examples 14 Through 18

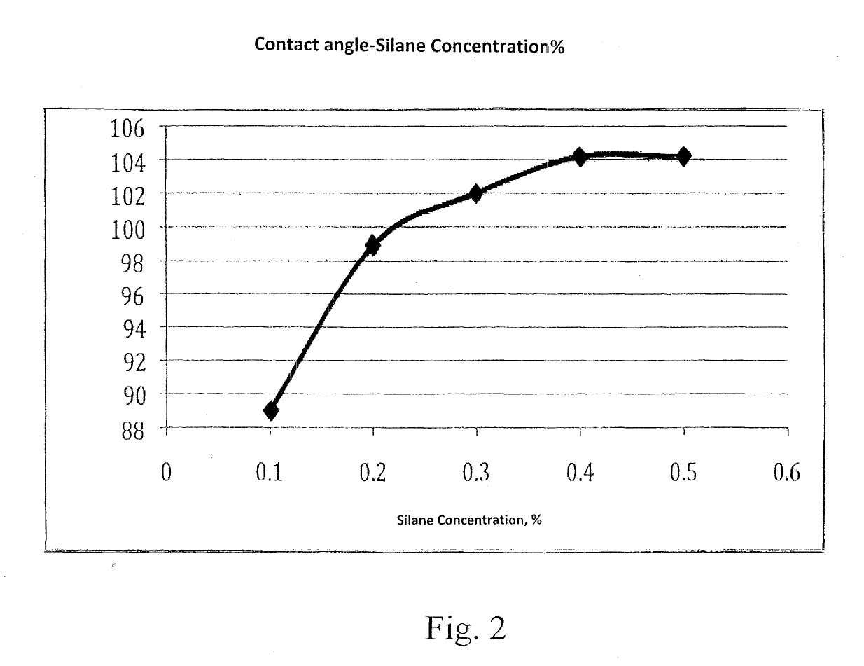

The solutions from Examples 14 through 18 were each spin-coated onto a 100-mm silicon wafer using a spin coater (Cee® 100CB from Brewer Science, Inc., Rolla, Mo.) at a spin speed of 1,250 rpm (250 rpm/s ramp) for 30 seconds, followed by baking on a hotplate (Cee® 100CB from Brewer Science, Inc., Rolla, Mo.) at 220° C. for 120 seconds. Each of the coatings made from the solutions were good in quality based on visual observation. The contact angle with water of the resulting films was measured using a VCA Optima tool (AST Products, Inc., Billerica, Mass., USA). The measured contact angles vs. silane concentration are listed in Table 3 and shown in FIG. 2.

TABLE 3
Characterization of Examples 14-18 and Performance
as Coatings on Silicon Wafers

| | SILANE CON- | COATING | CONTACT ANGLE |
|---|---|---|---|
| SAMPLE | CENTRATION, % | QUALITY* | WITH WATER |
| Example 14 | 0.1 | Good | 89° |
| Example 15 | 0.2 | Good | 98.9° |
| Example 16 | 0.3 | Good | 102° |
| Example 17 | 0.4 | Good | 104.2° |
| Example 18 | 0.5 | Good | 104.2° |

*Based on visual observation.

I claim:

1. A temporary bonding method comprising:
providing a stack comprising:
a first substrate having a back surface and a front surface;
a bonding layer adjacent said front surface; and
a second substrate having a first surface, said first surface including a nonstick layer formed from a composition comprising:
a fluorinated silane; and
less than about 5% by weight total of fluorinated and perfluorinated solvents, based upon the total weight of the composition taken as 100% by weight, said nonstick layer being adjacent said bonding layer; and
separating said first and second substrates.

2. The method of claim 1, said composition further comprising a solvent selected from the group consisting of propylene glycol monomethyl ether, 1-butanol, hexyl alcohol, propoxy propanol, and mixtures thereof.

3. The method of claim 1, wherein said composition comprises less than about 1% by weight total of fluorinated and perfluorinated solvents.

4. The method of claim 1, wherein said fluorinated silane is selected from the group consisting of (heptadecafluoro-1,1,2,2-tetrahydrodecyl)trichlorosilane, (heptadecafluoro-1,1,2,2-tetrahydrodecyl)trimethoxysilane), (heptadecafluoro-1,1,2,2-tetrahydrodecyl)dimethylchlorosilane, (heptadecafluoro-1,1,2,2-tetrahydrodecyl)methyldichlorosilane, (3-heptafluoroisopropoxy)propyltrichlorosilane, (tridecafluoro-1,1,2,2-tetrahydrooctyl)trichlorosilane, (tridecafluoro-1,1,2,2-tetrahydrooctyl)triethoxysilane, (tridecafluoro-1,1,2,2-tetrahydrooctyl)trimethoxysilane, (tridecafluoro-1,1,2,2-tetrahydrooctyl)dimethylchlorosilane, (tridecafluoro-1,1,2,2-tetrahydrooctyl)methyldichlorosilane, and mixtures of the foregoing.

5. The method of claim 1, wherein said composition further comprises an ingredient selected from the group consisting of catalysts, water, and mixtures thereof.

6. The method of claim 1, wherein said method further comprises forming said nonstick layer by applying said composition to said first surface.

7. The method of claim 6, wherein said applying comprises spin-coating said layer on said first surface.

8. The method of claim 1, wherein said bonding layer is formed from a composition comprising a polymer or oligomer dissolved or dispersed in a solvent system, said polymer or oligomer being selected from the group consisting of polymers and oligomers of cyclic olefins, epoxies, acrylics, silicones, styrenics, vinyl halides, vinyl esters, polyamides, polyimides, polysulfones, polyethersulfones, cyclic olefins, polyolefin rubbers, and polyurethanes, ethylene-propylene rubbers, polyamide esters, polyimide esters, polyacetals, and polyvinyl buterol.

9. The method of claim 1, wherein said front surface is a device surface that comprises an array of devices selected from the group consisting of integrated circuits; MEMS; microsensors; power semiconductors; light-emitting diodes; photonic circuits; interposers; embedded passive devices; and microdevices fabricated on or from silicon, silicon-germanium, gallium arsenide, and gallium nitride.

10. The method of claim 1, wherein said first surface is a device surface that comprises an array of devices selected from the group consisting of integrated circuits; MEMS; microsensors; power semiconductors; light-emitting diodes; photonic circuits; interposers; embedded passive devices; and microdevices fabricated on or from silicon, silicon-germanium, gallium arsenide, and gallium nitride.

11. The method of claim 1, wherein said second substrate comprises a material selected from the group consisting of silicon, sapphire, quartz, metal, glass, and ceramics.

12. The method of claim 1, wherein said first substrate comprises a material selected from the group consisting of silicon, sapphire, quartz, metal, glass, and ceramics.

13. The method of claim 1, wherein said front surface is a device surface comprising at least one structure selected from the group consisting of: solder bumps; metal posts; metal pillars; and structures formed from a material selected from the group consisting of silicon, polysilicon, silicon dioxide, silicon (oxy)nitride, metal, low k dielectrics, polymer dielectrics, metal nitrides, and metal silicides.

14. The method of claim 1, wherein said first surface is a device surface comprising at least one structure selected from the group consisting of: solder bumps; metal posts; metal pillars; and structures formed from a material selected from the group consisting of silicon, polysilicon, silicon dioxide, silicon (oxy)nitride, metal, low k dielectrics, polymer dielectrics, metal nitrides, and metal silicides.

15. The method of claim 1, further comprising subjecting said stack to processing selected from the group consisting of back-grinding, chemical-mechanical polishing, etching, metal and dielectric deposition, patterning, passivation, annealing, and combinations thereof, prior to separating said first and second substrates.

16. The method of claim 1, wherein said separating comprises heating said stack to a temperature sufficiently high so as to soften said bonding layer sufficiently to allow said first and second substrates to be separated.

17. The method of claim 16, further comprising removing said bonding layer from said first substrate after said separating.

18. An article comprising:
a first substrate having a back surface and a front surface;
a bonding layer adjacent said front surface; and
a second substrate having a first surface, said first surface including a nonstick layer formed from a composition comprising:
a fluorinated silane; and
less than about 5% by weight total of fluorinated and perfluorinated solvents, based upon the total weight of the composition taken as 100% by weight; and said nonstick layer being adjacent said bonding layer.

19. The article of claim 18, said composition further comprising a solvent selected from the group consisting of propylene glycol monomethyl ether, 1-butanol, hexyl alcohol, propoxy propanol, and mixtures thereof.

20. The article of claim 18, wherein said composition comprises less than about 1% by weight total of fluorinated and perfluorinated solvents.

21. The article of claim 18, wherein said fluorinated silane is selected from the group consisting of (heptadecafluoro-1,1,2,2-tetrahydrodecyl)trichlorosilane, (heptadecafluoro-1,1,2,2-tetrahydrodecyl)trimethoxysilane), (heptadecafluoro-1,1,2,2-tetrahydrodecyl)dimethylchlorosilane, (heptadecafluoro-1,1,2,2-tetrahydrodecyl)methyldichlorosilane, (3-heptafluoroisopropoxy)propyltrichlorosilane, (tridecafluoro-1,1,2,2-tetrahydrooctyl)trichlorosilane, (tridecafluoro-1,1,2,2-tetrahydrooctyl)triethoxysilane, (tridecafluoro-1,1,2,2-tetrahydrooctyl)trimethoxysilane, (tridecafluoro-1,1,2,2-tetrahydrooctyl)dimethylchlorosilane, (tridecafluoro-1,1,2,2-tetrahydrooctyl)methyldichlorosilane, and mixtures of the foregoing.

22. The article of claim 18, wherein said composition further comprises an ingredient selected from the group consisting of catalysts, water, and mixtures thereof.

23. The article of claim 18, wherein said bonding layer is formed from a composition comprising a polymer or oligomer dissolved or dispersed in a solvent system, said polymer or oligomer being selected from the group consisting of polymers and oligomers of cyclic olefins, epoxies, acrylics, silicones, styrenics, vinyl halides, vinyl esters, polyamides, polyimides, polysulfones, polyethersulfones, cyclic olefins, polyolefin rubbers, and polyurethanes, ethylene-propylene rubbers, polyamide esters, polyimide esters, polyacetals, and polyvinyl buterol.

24. The article of claim 18, wherein said front surface is a device surface that comprises an array of devices selected from the group consisting of integrated circuits; MEMS; microsensors; power semiconductors; light-emitting diodes; photonic circuits; interposers; embedded passive devices; and microdevices fabricated on or from silicon, silicon-germanium, gallium arsenide, and gallium nitride.

25. The article of claim 18, wherein said first surface is a device surface that comprises an array of devices selected from the group consisting of integrated circuits; MEMS; microsensors; power semiconductors; light-emitting diodes; photonic circuits; interposers; embedded passive devices; and microdevices fabricated on or from silicon, silicon-germanium, gallium arsenide, and gallium nitride.

26. The article of claim 18, wherein said second substrate comprises a material selected from the group consisting of silicon, sapphire, quartz, metal, glass, and ceramics.

27. The article of claim 18, wherein said first substrate comprises a material selected from the group consisting of silicon, sapphire, quartz, metal, glass, and ceramics.

28. The article of claim 18, wherein said front surface is a device surface comprising at least one structure selected from the group consisting of: solder bumps; metal posts; metal pillars; and structures formed from a material selected from the group consisting of silicon, polysilicon, silicon dioxide, silicon (oxy)nitride, metal, low k dielectrics, polymer dielectrics, metal nitrides, and metal silicides.

29. The article of claim 18, wherein said first surface is a device surface comprising at least one structure selected from the group consisting of: solder bumps; metal posts; metal pillars; and structures formed from a material selected from the group consisting of silicon, polysilicon, silicon dioxide, silicon (oxy)nitride, metal, low k dielectrics, polymer dielectrics, metal nitrides, and metal silicides.
